(19) United States
(12) Patent Application Publication
(10) Pub. No.: US 2026/0367502 A1
(43) Pub. Date: Nov. 19, 2026

(54) MASKS, METHODS OF MANUFACTURING MASKS, AND METHODS OF MANUFACTURING SEMICONDUCTOR DEVICE

(71) Applicant: Taiwan Semiconductor Manufacturing Company, Ltd., Hsinchu (TW)

(72) Inventors: Chun-Lang CHEN, Madou (TW); Chung-Yang HUANG, Lioujiao (TW); Shih-Hao YANG, Tainan (TW); Wei-Ting CHEN, Tainan (TW); Chien Yun HUANG, Kaohsiung (TW)

(73) Assignee: Taiwan Semiconductor Manufacturing Company, Ltd., Hsinchu (TW)

(21) Appl. No.: 19/752,273

(22) Filed: Jul. 23, 2026

Related U.S. Application Data
(63) Continuation of application No. 18/924,289, filed on Oct. 23, 2024.

(51) Int. Cl. G03F 1/48; G03F 1/24

(52) U.S. Cl. CPC G03F 1/48; G03F 1/24

(57) ABSTRACT

A mask includes a reflective multilayered stack, a capping layer over the reflective multilayered stack, an absorber layer over the capping layer, and at least one of: a buffer layer between the reflective multilayered stack and the capping layer, and a protection layer between the capping layer and the absorber layer. A method of manufacturing a mask includes forming a reflective multilayered stack, forming a capping layer over the reflective multilayered stack, forming an absorber layer over the capping layer, and forming at least one of the following: a buffer layer over the reflective multilayered stack before forming the capping layer, and a protection layer over the capping layer before forming the absorber layer. A method of manufacturing a semiconductor device includes directing radiation to a mask and reflecting patterned light from the mask and onto a photoresist layer disposed on a substrate.

### RELATED APPLICATION

This application is a Continuation of U.S. patent application Ser. No. 18/924,289 filed Oct. 23, 2024, the entire contents of which are incorporated herein by reference.

### BACKGROUND

Manufacturing challenges can arise when seeking to reduce the size and increase the complexity of semiconductor devices. When addressing such challenges, advanced lithography technologies, e.g., extreme ultraviolet (EUV) photolithography, have been utilized in semiconductor device manufacturing processes. EUV lithography employs a reflective photomask to irradiate a photoresist with patterned EUV radiation. The patterned photoresist can be used to form a pattern on a substrate. However, processes associated with manufacturing and cleaning a photomask used in EUV lithography can adversely affect the performance of the photomask.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 shows an EUV lithography tool according to an embodiment of the disclosure.

FIG. 2 shows a schematic diagram of a detail of an EUV lithography tool according to an embodiment of the disclosure.

FIG. 3 shows a cross-sectional view of an EUV mask according to an embodiment of the disclosure.

FIGS. 4, 5, 6, 7, 8, and 9 show cross-sectional views of a method of manufacturing an EUV mask according to an embodiment of the disclosure.

FIGS. 10, 11, 12, and 13 show cross-sectional views of a method of manufacturing an EUV mask according to an embodiment of the disclosure.

FIGS. 14, 15, and 16 show cross-sectional views of a method of manufacturing an EUV mask according to an embodiment of the disclosure.

FIG. 17 is a flow chart of a method of manufacturing a mask according to an embodiment of the disclosure.

FIG. 18 is a flow chart of a method of manufacturing a semiconductor device according to an embodiment of the disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper,” “top,” “bottom,” “middle,” and the like, may be used herein for ease of description to describe one element or feature's relationship to another element(s) or feature(s) as illustrated in the figures, and do not preclude additional structures above or below or between the stated feature. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Further, in the following fabrication process, there may be one or more additional operations in between the described operations, and the order of operations may be changed. In the present disclosure, a phrase “one of A, B and C” means “A, B and/or C (A, B, C, A and B, A and C, B and C, or A, B and C), and does not mean one element from A, one element from B and one element from C, unless otherwise described. In the following embodiments, materials, configurations, dimensions, processes and/or operations as described with respect to one embodiment (e.g., one or more figures) may be employed in the other embodiments, and detailed description thereof may be omitted.

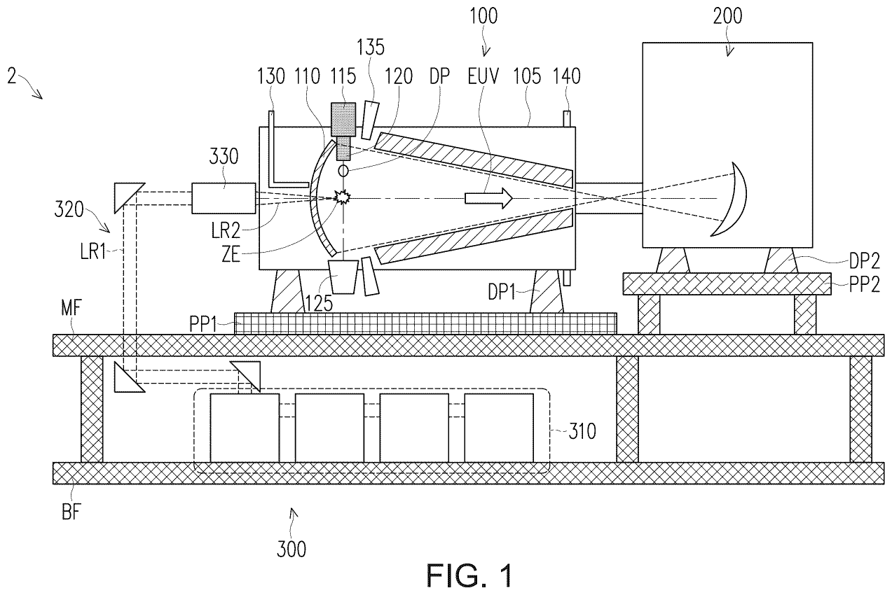

FIG. 1 is a schematic view of an EUV lithography tool 2, in accordance with some embodiments of the present disclosure. The EUV lithography tool 2 includes an EUV radiation source 100 to generate EUV radiation, an exposure device 200 such as a scanner, and an excitation laser source 300. The EUV radiation source 100 and the exposure device 200 are installed on a main floor MF of a clean room, while the excitation laser source 300 is installed in a base floor BF located under the main floor. Each of the EUV radiation source 100 and the exposure device 200 are placed over pedestal plates PP1 and PP2 via dampers DP1 and DP2, respectively. The EUV radiation source 100 and the exposure device 200 are coupled to each other by a coupling mechanism, which may include a focusing unit.

The EUV lithography tool 2 is designed to expose a resist layer to EUV light (also interchangeably referred to herein as EUV radiation). The resist layer is a material sensitive to the EUV light. The EUV lithography system employs the EUV radiation source 100 to generate EUV light, such as EUV light having a wavelength ranging between about 1 nm and about 100 nm. In one particular example, the EUV radiation source 100 generates an EUV light with a wavelength centered at about 13.5 nm. In the present embodiment, the EUV radiation source 100 utilizes a mechanism of laser-produced plasma (LPP) to generate the EUV radiation.

The exposure device 200 includes various reflective optic components, such as convex/concave/flat mirrors, a mask holding mechanism including a mask stage, and wafer holding mechanism. The EUV radiation generated by the EUV radiation source 100 is guided by the reflective optical components onto a mask secured on the mask stage. In some embodiments, the mask stage includes an electrostatic chuck (e-chuck) to secure the mask.

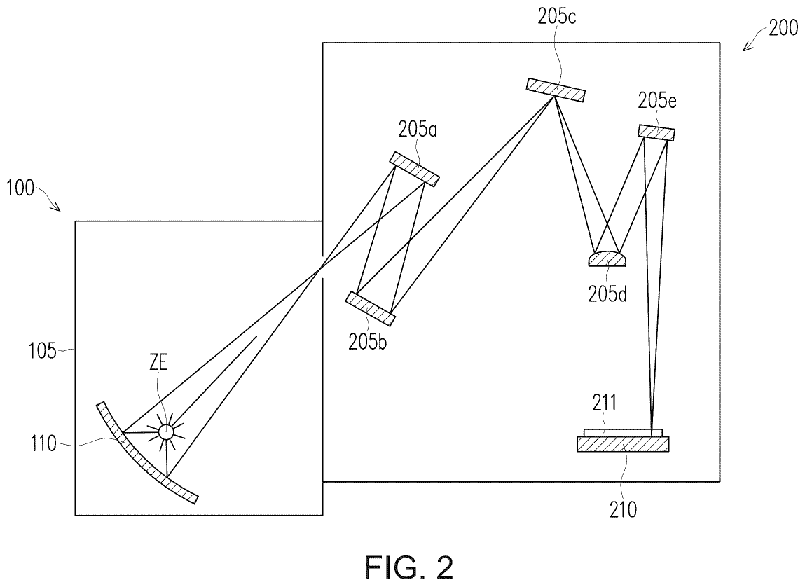

FIG. 2 is a simplified schematic diagram of a detail of an extreme ultraviolet lithography tool according to an embodiment of the disclosure showing the exposure of photoresist 211 coated on a substrate 210 with a patterned beam of EUV light. The exposure device 200 is an integrated circuit lithography tool such as a stepper, scanner, step and scan system, direct write system, a device using a contact and/or proximity mask, etc., provided with one or more optics 205a, 205b, for example, to illuminate mask 205c (also referred to as a reticle or photomask) with a beam of EUV light, to produce a patterned beam, and one or more reduction projection optics 205d, 205e, for projecting the patterned beam onto the photoresist 211 disposed on the substrate 210. In the present embodiment, the mask 205c is a reflective mask. A mechanical assembly (not shown) may be provided for generating a controlled relative movement between the substrate 210 and mask 205c. The EUV radiation source 100 includes an EUV light radiator ZE emitting EUV light in a chamber 105 that is reflected by a mirror collector 110 along a path into the exposure device 200 to irradiate the photoresist layer 211 on the substrate 210. In some embodiments, the substrate 210 is a semiconductor substrate. In some embodiments, a semiconductor substrate is a semiconductor wafer, such as a silicon wafer or other type of wafer to be patterned.

As shown in FIG. 1, the EUV radiation source 100 includes a target droplet generator 115 and a mirror collector 110, enclosed by a chamber 105. In some embodiments, the target droplet generator 115 includes a reservoir to hold a source material and a nozzle 120 through which target droplets DP of the source material are supplied into the chamber 105. In some embodiments, the target droplets DP are droplets of tin (Sn), lithium (Li), or an alloy of Sn and Li. In some embodiments, the target droplets DP each have a diameter in a range from about 10 microns (μm) to about 100 μm. For example, in an embodiment, the target droplets DP are tin droplets, having a diameter of about 10 μm to about 100 μm. In other embodiments, the target droplets DP are tin droplets having a diameter of about 25 μm to about 50 μm. In some embodiments, the target droplets DP are supplied through the nozzle 120 at a rate in a range from about 50 droplets per second (i.e., an ejection-frequency of about 50 Hz) to about 50,000 droplets per second (i.e., an ejection-frequency of about 50 kHz). A droplet catcher 125 is used for catching excessive target droplets. For example, some target droplets may be purposely missed by laser pulses.

In some embodiments, an excitation laser LR2 generated by the excitation laser source 300 is a pulse laser. The excitation laser source 300 may include a laser generator 310, laser guide optics 320, and a focusing apparatus 330. In some embodiments, a laser generator 310 includes a carbon dioxide (CO₂) or a neodymium-doped yttrium aluminum garnet (Nd:YAG) laser source with a wavelength in the infrared region of the electromagnetic spectrum. For example, the a laser generator 310 has a wavelength of 9.4 μm or 10.6 μm, in an embodiment. The laser light LR1 generated by the excitation laser source 300 is guided by the laser guide optics 320 and focused into the excitation laser LR2 by the focusing apparatus 330, and then introduced into the EUV radiation source 100.

In some embodiments, the excitation laser LR2 includes a pre-heat laser and a main laser. In such embodiments, the pre-heat laser pulse (interchangeably referred to herein as the “pre-pulse) is used to heat (or pre-heat) a given target droplet to create a low-density target plume with multiple smaller droplets, which is subsequently heated (or reheated) by a pulse from the main laser, generating increased emission of EUV light. In some embodiments, the pre-heat laser pulses have a spot size about 100 μm or less, and the main laser pulses have a spot size in a range of about 150 μm to about 300 μm. In some embodiments, the pre-heat laser and the main laser pulses have a pulse-duration in the range from about 10 ns to about 50 ns, and a pulse-frequency in the range from about 1 kHz to about 100 kHz. In some embodiments, the pre-heat laser and the main laser have an average power in the range from about 1 kilowatt (kW) to about 50 kW. The pulse-frequency of the excitation laser LR2 is matched with the ejection frequency of the target droplets DP in an embodiment.

The excitation laser LR2 is directed through windows (or lenses) into the zone of excitation ZE. The windows are made of a suitable material substantially transparent to the laser beams. The generation of the pulse lasers is synchronized with the ejection of the target droplets DP through the nozzle 120. As the target droplets move through the excitation zone, the pre-pulses heat the target droplets and transform them into low-density target plumes. A delay between the pre-pulse and the main pulse is controlled to allow the target plume to form and to expand to an optimal size and geometry. In some embodiments, the pre-pulse and the main pulse have the same pulse duration and peak power. When the main pulse heats the target plume, a high-temperature plasma is generated. The plasma emits EUV radiation, which is collected by the mirror collector 110. The mirror collector 110 further reflects and focuses the EUV radiation for the lithography exposing processes performed through the exposure device 200. In some embodiments, the mirror collector 110 is designed to have an ellipsoidal geometry. In some embodiments, the mirror collector 110 is designed with a proper coating material and shape to function as a mirror for EUV collection, reflection, and focusing.

In some embodiments, a coating material of the mirror collector 110 is similar to a reflective multilayer of the EUV mask. In some examples, a coating material of the mirror collector 110 includes a reflective multilayer (such as a plurality of Mo/Si film pairs) and may further include a capping layer (such as Ru) coated on the reflective multilayer to substantially reflect the EUV light. In some embodiments, the mirror collector 110 may further include a grating structure designed to effectively scatter the laser beam directed onto the mirror collector 110. For example, a silicon nitride layer is coated on the mirror collector 110 and is patterned to have a grating pattern.

In such an EUV radiation source 100, the plasma caused by the laser application creates physical debris, such as ions, gases and atoms of the droplet, as well as the desired EUV radiation. It is necessary to prevent the accumulation of material on the mirror collector 110 and also to prevent physical debris exiting the chamber 105 and entering the exposure device 200.

Because gas molecules absorb EUV light, the lithography system for the EUV lithography patterning can be maintained in a vacuum or a low-pressure environment to avoid EUV intensity loss. In some embodiments, a buffer gas is supplied from a first buffer gas supply 130 through the aperture in the mirror collector 110 by which the pulse laser is delivered to the tin droplets. In some embodiments, the buffer gas is H₂, He, Ar, N₂ or another inert gas. The buffer gas can also be provided through one or more second buffer gas supplies 135 toward the mirror collector 110 and/or around the edges of the mirror collector 110. Further, the chamber 105 includes one or more gas outlets 140 so that the buffer gas is exhausted outside the chamber 105. Hydrogen gas (H₂) has a low absorption to the EUV radiation. In certain embodiments, hydrogen gas can be energized by EUV radiation to generate hydrogen (H*) radicals. The hydrogen radicals can be used for cleaning purposes. Hydrogen radicals reaching the coating surface of the mirror collector 110 can react chemically with metal contamination from a droplet and form a hydride, e.g., metal hydride. When tin (Sn) is used as the droplet, hydrogen radicals can react with tin to form stannane (SnH₄), which is a gaseous byproduct of the EUV generation process. The gaseous SnH₄ can then then pumped out through the outlet 140.

In some embodiments, an EUV lithography tool can further include other modules or is integrated with (or coupled with) other modules in some embodiments.

A mask used in EUV lithography can include a reflective multilayered stack disposed over a substrate, a capping layer disposed over the reflective multilayered stack, and an absorber layer disposed over the capping layer. Oxidation of the capping layer, and possibly an upper portion of a reflective multilayered stack, can undesirably occur during one or more of mask fabrication and cleaning processes. For example, circuit patterns and black border patterns can be formed in a mask using one or more etching operations (e.g., O₂ plasma etching). A mask can be cleaned using a cleaning solution (e.g., sulfuric acid). Oxidation can occur during such fabrication and cleaning processes. Oxidation can decrease the reflectivity of one or more of the capping layer and the reflective multilayer structure. Oxidation of a portion of the reflective multilayer structure can also cause the reflective multilayer structure to expand and deform the mask. Thus, oxidation can decrease the lifetime of a mask. Provided herein are structures and methods for protecting a mask from undesired oxidation.

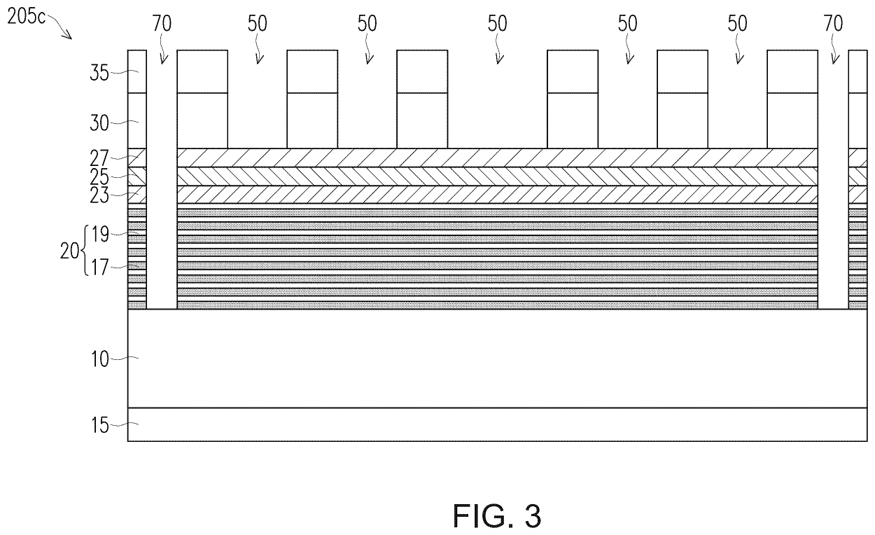

A mask can include a substrate made of a low thermal expansion material, such as titanium oxide doped silicon dioxide, or any other suitable low thermal expansion materials, such as fused silica, fused quartz, silicon, silicon carbide, Black Diamond, and/or any one or more other low thermal expansion substances known in the art that can minimize the image distortion due to mask heating in the EUV photolithographic environment. The mask substrate can have a low defect level, such as a high purity single crystal substrate, and have a low level of surface roughness as measured using an atomic force microscope. The mask substrate can transmit light within a predetermined spectrum, such as visible wavelengths, infrared wavelengths near the visible spectrum (near-infrared), and ultraviolet wavelengths. In some embodiments, the mask substrate absorbs EUV wavelengths and DUV wavelengths. FIG. 3 shows a cross-sectional view of an embodiment of a mask 205c including a mask substrate 10 made of a suitable material, such as a low thermal expansion material, according to an embodiment of the present disclosure.

A mask can include a reflective multilayered stack formed over a mask substrate. A reflective multilayered stack can include a plurality of film pairs, such as molybdenum-silicon (Mo/Si) film pairs (e.g., a layer of molybdenum above or below a layer of silicon in each film pair). Alternatively, a reflective multilayered stack may include molybdenum-beryllium (Mo/Be) film pairs, or other suitable materials that are configured to highly reflect EUV light. FIG. 3 shows a reflective multilayered stack 20 including alternating molybdenum layers 17 and silicon layers 19 disposed over a first major surface of the mask substrate 10. In some embodiments, the multilayered stack 20 provides Fresnel resonant reflections across the interfaces between the Mo layer and Si layer, which have different refractive indices and appropriate thicknesses. The thickness of the layers can depend on the wavelength of the incident light and the angle of incidence of the light to be used with the EUV mask. For a specific angle of incidence, the thickness of each of the layers of the multilayered stack 20 can be chosen to achieve maximal constructive interference for light reflected at different interfaces of the multilayered stack 20. An even thickness and low surface roughness of each of the layers in the multilayered stack 20 can provide high-quality Fresnel resonant reflections. In some embodiments, a thickness of each of the layers in the multilayered stack 20 is 5-7 nm. In some embodiments, the number of layers in the multilayered stack 20 is in a range from 20 to 100, although any number of layers is allowed as long as sufficient reflectivity is maintained for imaging a photoresist layer over a target substrate. In some embodiments, a reflectivity of a reflective multilayered stack is higher than about 70%. In some embodiments, the multilayer stack 20 includes about 30 to about 60 alternating layers of Mo and Si. In other embodiments, the multilayer stack 20 includes about 40 to about 50 alternating layers each of Mo and Si. The alternating layers, e.g., Si layers and Mo layers, of the reflective multilayered stack 20 may be formed by any one or more of atomic layer deposition (ALD), physical vapor deposition (PVD), chemical vapor deposition (CVD), plasma-enhanced CVD (PECVD).

A mask 205c can include a buffer layer disposed over a reflective multilayered stack. FIG. 3 illustrates a buffer layer 23 disposed over the multilayered stack 20. In some embodiments, the buffer layer 23 is made of a transition metal composition, and alternatively or additionally, a metal oxide, a metal nitride, amorphous carbon, or other suitable materials. In some embodiments, the buffer layer 23 is made of one or more transition metal elements. Embodiments of transition metal elements that are useful in a buffer layer include tantalum, ruthenium, niobium, and rhodium. In some embodiments, the buffer layer 23 is made of an alloy of two or more transition metal elements. In some embodiments, the buffer layer 23 is made of a compound including one or more transition metal elements. In some embodiments, the buffer layer 23 is made of any of one or more of a halide, an oxide, a nitride, a carbide, or a boride of one or more transition metal elements. Examples of halides that are useful for a buffer layer include fluorides, chlorides, bromides, and iodides. In some embodiments, the buffer layer 23 is made of one or more of tantalum oxide, ruthenium oxide, niobium oxide, rhodium oxide, tantalum nitride, ruthenium nitride, niobium nitride, rhodium nitride, tantalum carbide, ruthenium carbide, niobium carbide, rhodium carbide, tantalum boride, ruthenium boride, niobium boride, rhodium boride, tantalum fluoride, ruthenium fluoride, niobium fluoride, rhodium fluoride, tantalum chloride, ruthenium chloride, niobium chloride, rhodium chloride, tantalum bromide, ruthenium bromide, niobium bromide, rhodium bromide, tantalum iodide, ruthenium iodide, niobium iodide, and rhodium iodide.

In some embodiments, the buffer layer 23 is formed by one or more of ion beam deposition (IBD), ALD, PVD, CVD, and PECVD. In some embodiments, the buffer layer 23 has a thickness ranging from about 0.5 nm to about 10 nm, from about 1 nm to about 9 nm, from about 2 nm to about 8 nm, from about 3 nm to about 7 nm, or from about 4 nm to about 6 nm.

The mask 205c can include a capping layer 25 disposed over the reflective multilayered stack 20. In some forms, a buffer layer 23 is disposed over a reflective multilayered stack 20 and a capping layer 25 is disposed over the buffer layer 23 with the buffer layer between the reflective multilayered stack and the capping layer. The buffer layer 23 can protect the reflective multilayered stack 20 from oxidation during fabrication processes. Accordingly, the buffer layer can protect and stabilize a reflective multilayered stack. FIG. 3 illustrates a capping layer 25 disposed over the buffer layer 23, which is disposed over the multilayered stack 20. In other embodiments, the capping layer 25 is disposed directly on a reflective multilayered stack and no buffer layer is disposed between the capping layer 25 and the reflective multilayered stack 20. In some embodiments, the capping layer is made of one or more of tantalum, ruthenium, niobium, rhodium, tantalum oxide, ruthenium oxide, niobium oxide, rhodium oxide, tantalum fluoride, ruthenium fluoride, niobium fluoride, rhodium fluoride, tantalum chloride, ruthenium chloride, niobium chloride, rhodium chloride, and an alloy of two or more of tantalum, ruthenium, niobium, rhodium. In some embodiments, the capping layer 25 is formed by one or more of ALD, PVD, CVD, and PECVD. In some embodiments, a capping layer 25 has a thickness ranging from about 1 nm to about 7 nm, from about 2 nm to about 6 nm, or from about 3 nm to about 5 nm.

A mask can include a protection layer disposed over a capping layer. FIG. 3 shows an embodiment of a protection layer 27 disposed on a capping layer 25. The protection layer can protect the capping layer 25 and an underlying reflective multilayered stack 20 from oxidation during mask fabrication and cleaning processes. In some embodiments, the protection layer 27 is made of a transition metal composition, and alternatively or additionally, a metal oxide, a metal nitride, amorphous carbon, or other suitable materials. In some embodiments, the protection layer is made of one or more of a metal oxide, a metal compound oxide, and a metal halide. In some embodiments, the protection layer is made of one or more transition metal elements or an alloy of two or more transition metal elements. In some embodiments, the protection layer is made of one or more of ruthenium, rhodium, a ruthenium-rhodium alloy, and a ruthenium-rhodium alloy. In some embodiments, the protection layer 27 is made of a compound including one or more transition metal elements. In some embodiments, the protection layer 27 is made of one or more of an oxide including a transition metal element and an halide including a transition metal element. In some embodiments, the protection layer 27 is made of a transition metal oxide. In some embodiments, the protection layer 27 is made of a transition metal halide. In some embodiments, halides useful in the protection layer 27 include fluorides, chlorides, bromides, and iodides. In some embodiments, the protection layer 27 includes a transition metal chloride. In some embodiments, the protection layer 27 is made of one or more ruthenium oxide, ruthenium chloride, rhodium oxide, and rhodium chloride.

In some embodiments, the protection layer 27 is formed by one or more of IBD, ALD, PVD, CVD, or PECVD. When used to form a buffer layer or a protection layer, an IBD process can help reduce perturbation and defects in the surfaces of the formed layers because deposition conditions can be set in an IBD process to smooth over defects on a substrate. In some embodiments, the protection layer has a thickness ranging from about 0.5 nm to about 10 nm, from about 1 nm to about 9 nm, from about 2 nm to about 8 nm, from about 3 nm to about 7 nm, or from about 4 nm to about 6 nm. In some embodiments the capping layer 25 is disposed on the buffer layer 23, and the protection layer 27 is disposed on the capping layer 25, and a thickness of the buffer layer 23 is less than a thickness of the protection layer 27.

In some embodiments, the mask 205c includes a multilayer capping structure disposed over the reflective multilayered stack, and the multilayer capping structure includes a capping layer 25 and at least one of a buffer layer 23 disposed under the capping layer 25 and a protection layer 27 disposed over the capping layer 25. In some embodiments, the multilayer capping structure includes a capping layer 25 disposed over a buffer layer 23, and a protection layer 27 disposed over the capping layer 25. In some embodiments, the multilayer capping structure includes a capping layer 25 disposed over a buffer layer 23 and no protection layer disposed over the capping layer. In some embodiments, the multilayer capping structure includes a protection layer 27 disposed over a capping layer 25 and no buffer layer under the capping layer. In some embodiments of a mask 205c including one or more of a protection layer 27 and a buffer layer 23, the mask 205c exhibits a reflectivity of greater than about 63%. In some embodiments, the mask 205c includes a buffer layer 23 having a different composition than a capping layer 25. In some embodiments, the mask 205c includes a protection layer having a different composition than a capping layer. In some embodiments, the mask 205c includes both a buffer layer 23 and a protection layer 27, and the buffer layer and the protection layer have different compositions. In some embodiments of a mask including both a buffer layer and a protection layer, the buffer layer 23 and the protection layer 27 have the same composition.

The mask can include an absorber layer 30 disposed over a capping layer 25. In some embodiments, the absorber layer 30 is disposed over protection layer 27, and the protection layer 27 is disposed over a capping layer 25. FIG. 3 shows the absorber layer 30 disposed over the protection layer 27. In some embodiments of the mask 205c, the absorber layer 30 is disposed directly on the capping layer 25, and the mask includes no protection layer between the absorber layer and the capping layer. The absorber layer 30 can be configured to absorb radiation having a wavelength in a range of EUV radiation. The absorber layer 30 can be formed of a single layer or multiple layers. The thickness of the absorber layer is not limited as long as the overall reflectivity of a mask is more than 70%. The absorber layer 30 can be patterned by removing sections of the absorber layer. Portions of the absorber layer 30 remaining after patterning can absorb light and sections of the mask where the absorber layer has been removed can reflect a pattern of light that can be directed to a photoresist layer. The absorber layer 30 can be patterned to define a layer of an integrated circuit (IC). In some embodiments, a pattern such as a hole structure, a line structure, or a cavity structure can be formed in the absorber layer 30 so as to expose an underlying structure of a mask, such as the protection layer or the capping layer. In some embodiments, the absorber layer includes one or more of tantalum, boron, tantalum nitride, tantalum boron nitride, titanium, nickel, chromium, ruthenium, platinum, germanium, nickel, lanthanum, molybdenum, palladium, zirconium, nickel silicide, titanium nitride, chromium oxide, aluminum oxide, aluminum-copper alloy, an alloy including two or more thereof, or a compound including two or more thereof.

The mask 205c can include an anti-reflection layer 35 disposed over the absorber layer 30. In some embodiments, the anti-reflection layer 35 is made of one or more of silicon dioxide, silicon nitride, tantalum borate, tantalum pentoxide, chromium oxide (Cr₂O₃), or indium tin oxide (ITO). The anti-reflection layer 35 can reduce reflections of photolithographic radiation. FIG. 3 shows an anti-reflection layer 35 disposed over the absorber layer 30. The anti-reflection layer 35 can be patterned along with the absorber layer 30 by removing sections of the anti-reflection layer and the absorber layer to expose an underlying structure of a mask, such as a protection layer or a capping layer.

The mask 205c can include a conductive backside coating layer 15 on a major surface of a substrate 10 opposite the reflective multilayered stack 20. FIG. 3 shows a conductive backside coating layer 15 disposed on a second major surface of the substrate 10. The conductive backside coating layer 15 can be used to retain the mask 205c through electrostatic chucking during a photolithographic operation. In an embodiment, the conductive backside coating layer 15 is formed of a ceramic compound including chromium nitride or any suitable material for electrostatic chucking of the mask. In some embodiments, the conductive backside coating layer 15 includes chromium nitride (CrN), chromium oxynitride (CrON), or another suitable conductive material. In some embodiments, the conductive backside coating layer 15 has a thickness ranging from about 20 nm to about 100 nm. The conductive backside coating layer 15 can be formed by CVD, ALD, molecular beam epitaxy (MBE), PVD, pulsed laser deposition, electron-beam evaporation, ion beam assisted evaporation, or any other suitable film-forming method. In some embodiments, the conductive backside coating layer 15 covers an entire backside of the mask substrate 10. In some embodiments, the conductive backside coating layer 15 covers a fraction of a backside of a mask substrate 10.

In some embodiments, a mask blank includes an un-patterned absorber layer 30 and optionally an un-patterned anti-reflection layer 35 formed over one or more of a protection layer 27 and a capping layer 25. In some embodiments, a mask 205c includes a pattern formed in the absorber layer 30 and optionally the anti-reflection layer 35. In some embodiments of the mask 25c, the reflective multilayered stack 20, the capping layer 25, and one or more of the buffer layer 23 and the protection layer 27 reflect EUV radiation, while the absorber layer 30 absorbs the EUV radiation.

As shown in FIG. 3, one or more circuit patterns 50 are formed on the mask by partially removing the anti-reflection layer 35 and the absorber layer 30. In addition, the mask includes a black border area 70 surrounding a circuit pattern region. In some embodiments, the black border area penetrates below the reflective multilayered stack and into the substrate. Circuit patterns and black border areas can be formed by one or more etching operations (e.g., O₂ plasma etching).

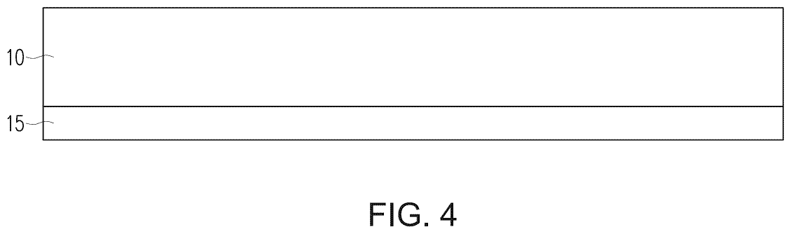

FIGS. 4 to 16 are cross-sectional views of embodiments of methods of manufacturing masks. It should be understood that additional operations can be provided before, during, and after the processes shown in FIGS. 4 to 16, and some of the operations described can be replaced or eliminated, and the order of the operations/processes may be changed.

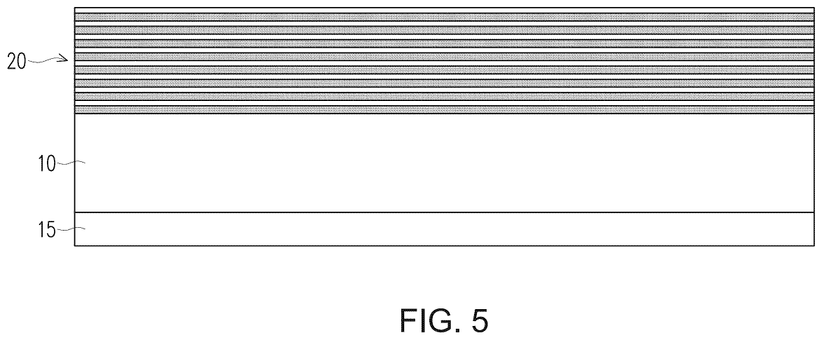

Referring to FIG. 4, a mask substrate 10 is provided, formed, or received. In some embodiments, a backside coating layer 15 is disposed on a backside of the substrate 10. In FIG. 5, a reflective multilayered stack 20 is formed over a front side of the substrate 10.

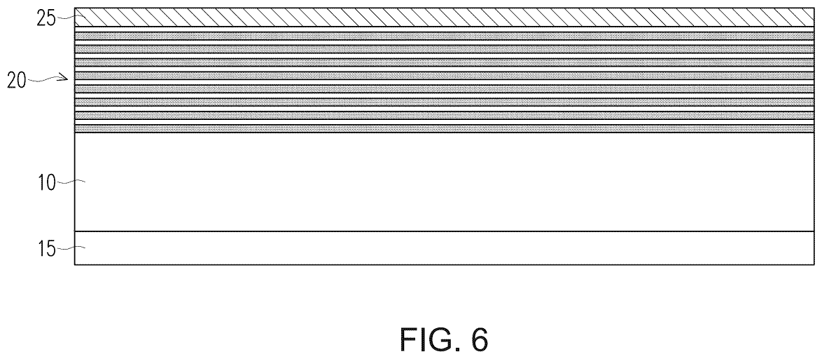

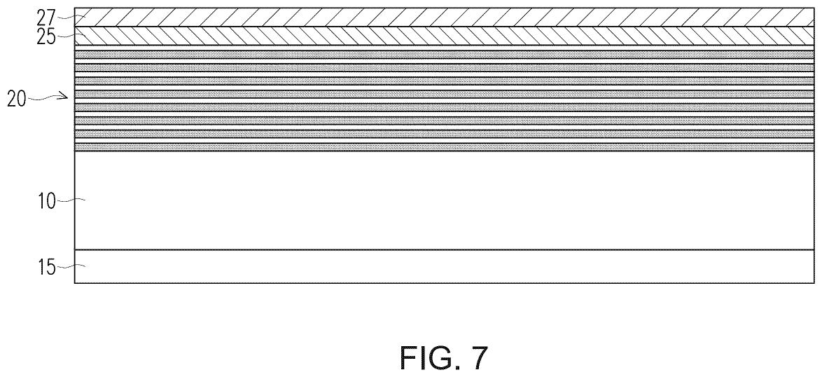

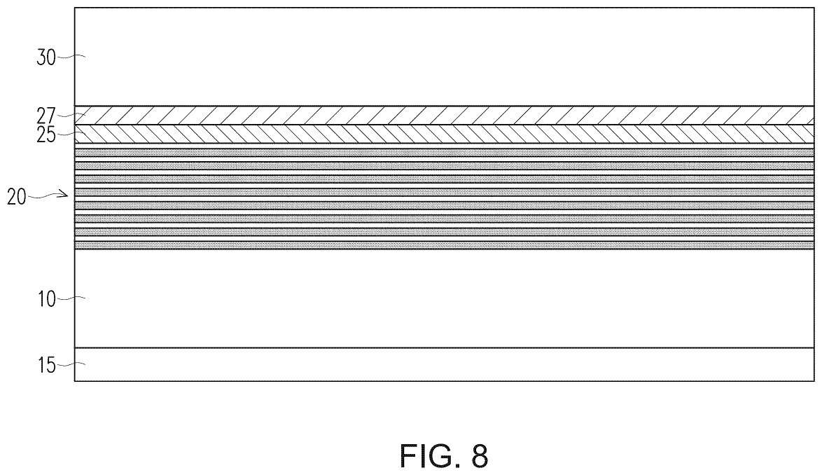

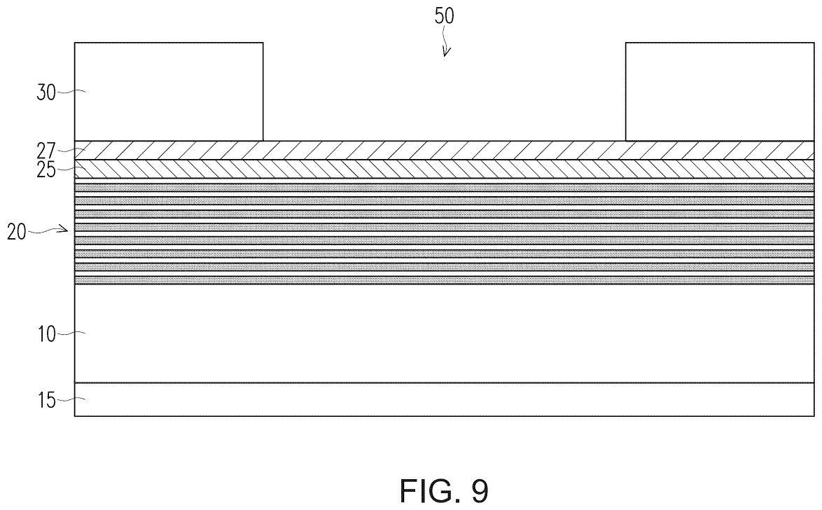

FIG. 6 illustrates an embodiment where a capping layer 25 is formed over the reflective multilayered stack 20 shown in FIG. 5. In FIG. 7, a protection layer 27 is formed over the capping layer 25. In FIG. 8, an absorber layer 30 is formed over the protection layer 27. In FIG. 9, circuit pattern 50 is formed in the absorber layer 30 to expose a portion of the protection layer 27.

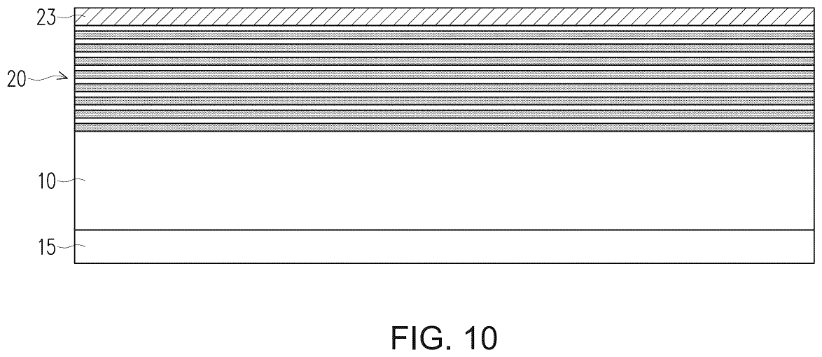

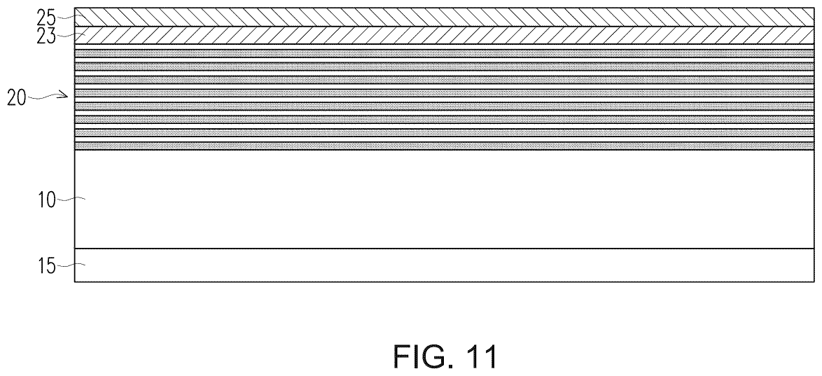

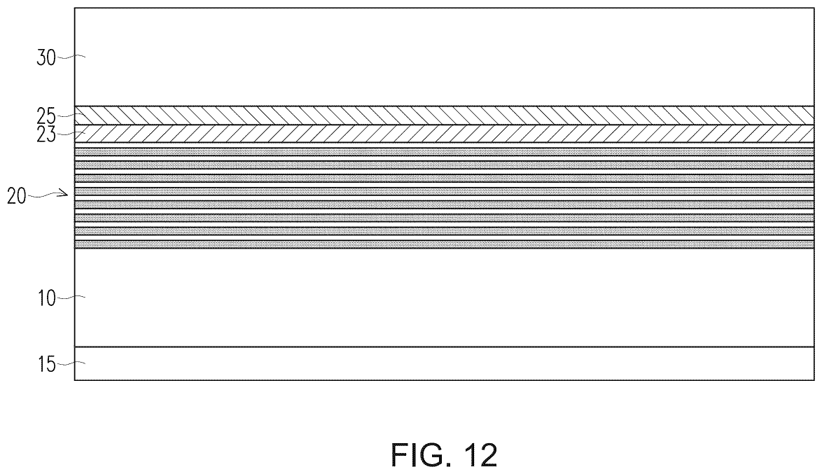

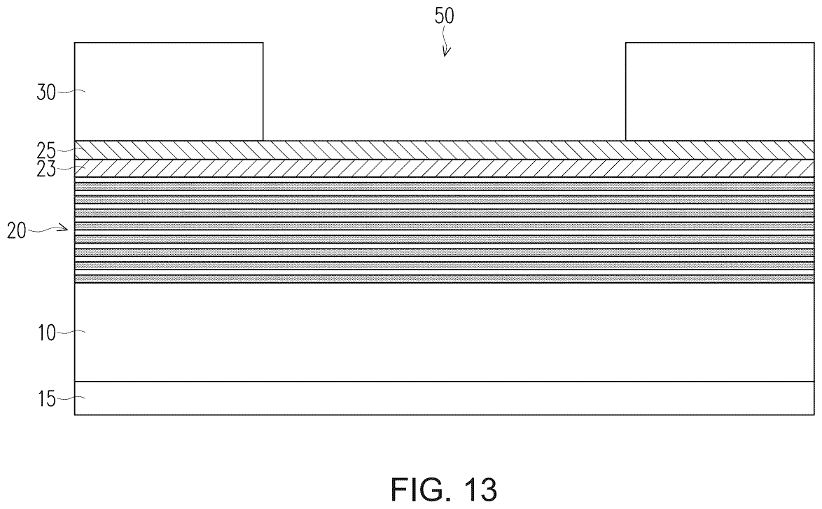

FIG. 10 illustrates another embodiment wherein a buffer layer 23 is formed over the reflective multilayered stack 20 shown in FIG. 5. In FIG. 11, a capping layer 25 is formed over the buffer layer 23. In FIG. 12, an absorber layer 30 is formed over the capping layer 25. In FIG. 13, a circuit pattern 50 is formed in the absorber layer 30 to expose a portion of the capping layer 25.

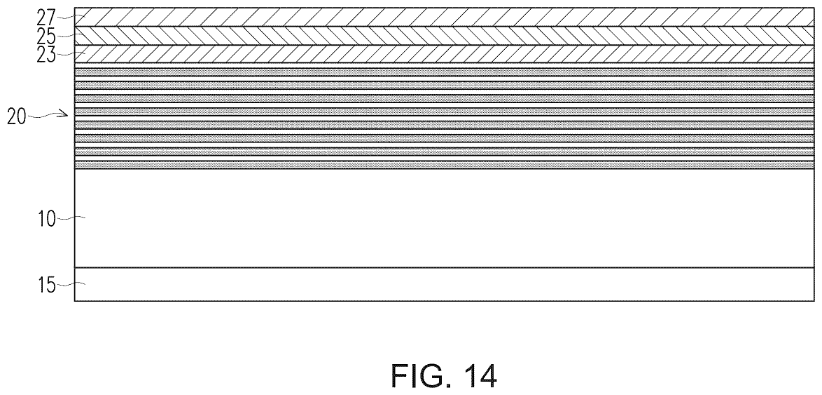

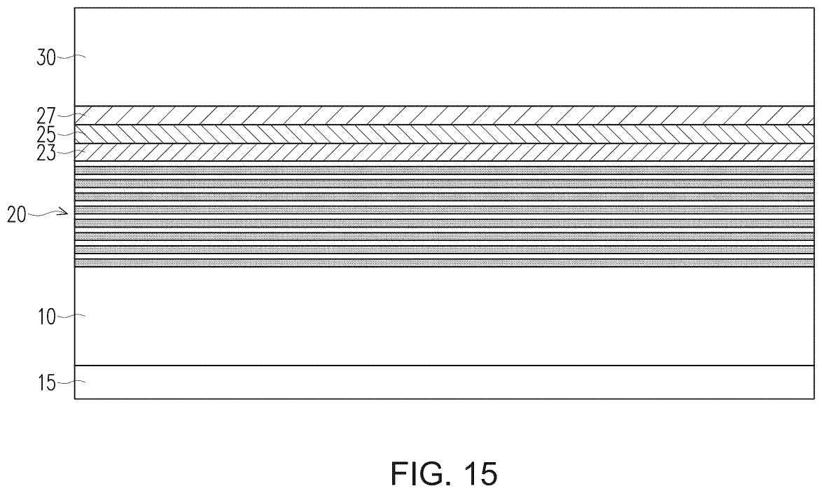

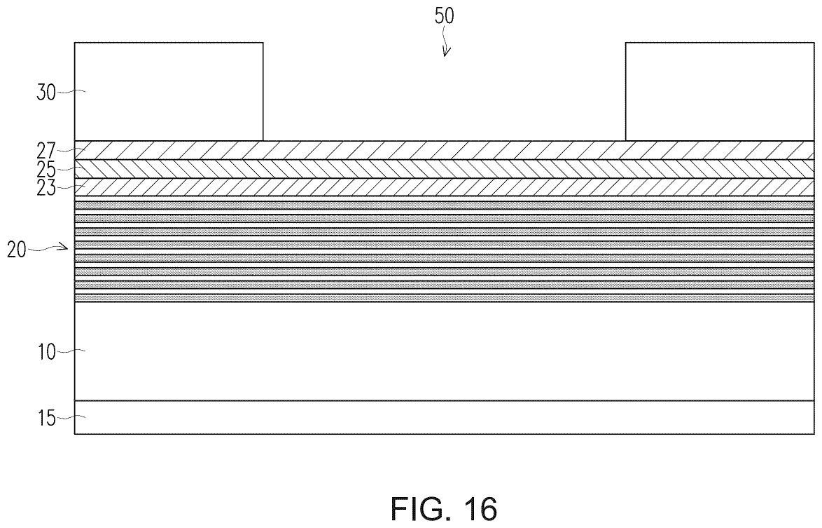

FIG. 14 illustrates another embodiment wherein a protection layer 27 is formed over the capping layer 25 shown in FIG. 11. In FIG. 15, an absorber layer 30 is formed over the protection layer 27. In FIG. 16, a circuit pattern 50 is formed in the absorber layer 30 to expose a portion of the protection layer 27.

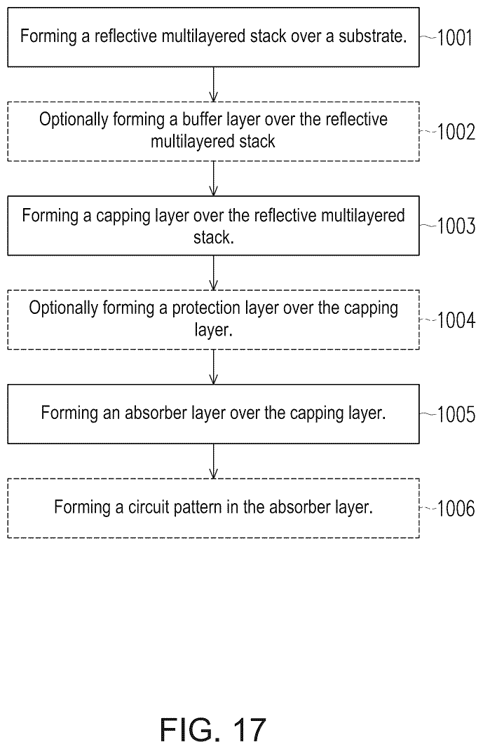

FIG. 17 shows a flow-chart of a method of manufacturing a mask according to some embodiments. The method includes an operation 1001 of forming a reflective multilayered stack 20 over a substrate 10. In some embodiments, the method includes an operation 1002 of forming a buffer layer 23 over the reflective multilayer stack 20. The method further includes an operation 1003 of forming a capping layer 25 over the reflective multilayered stack 20, and over the buffer layer 23 when the buffer layer is formed over the reflective multilayered stack. In some embodiments, the method includes an operation 1004 of forming a protection layer 27 over the capping layer 25. The method further includes an operation 1005 of forming an absorber layer 30 over the capping layer 25, and over the protection layer 27 when the protection layer is formed over the capping layer. In some embodiments, the method includes at least one of the operation 1002 of forming a buffer layer over the reflective multilayer stack before forming the capping layer, and the operation 1004 of forming a protection layer over the capping layer before the operation 1005 of forming the absorber layer. In some embodiments, the method includes an operation 1006 of forming a circuit pattern in the absorber layer.

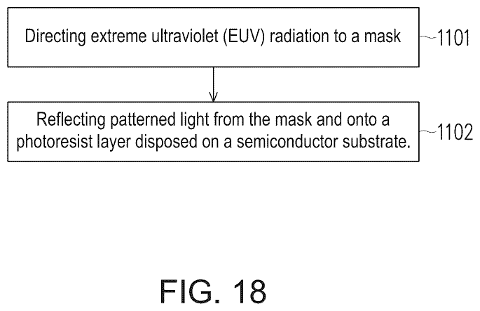

FIG. 18 shows a flow-chart of a method of manufacturing a semiconductor device according to some embodiments. The method includes an operation 1101 of directing EUV radiation to a mask and then an operation 1102 of reflecting patterned light from the mask and onto a photoresist layer disposed on a semiconductor substrate. The EUV exposed photoresist layer is subsequently developed to form a pattern. The pattern corresponds to an integrated circuit to be formed on the substrate. Additional semiconductor device manufacturing operations are subsequently performed to obtain a desired semiconductor device. In some embodiments, the desired semiconductor device includes active components such diodes, field-effect transistors (FETs), metal-oxide semiconductor field effect transistors (MOSFET), complementary metal-oxide semiconductor (CMOS) transistors, bipolar transistors, high voltage transistors, high frequency transistors, sheet FETs such as nanosheet FETs, FinFETs, gate-all-around FETs (GAA FETs), other three-dimensional (3D) FETs, other memory cells, and combinations thereof

A protection layer of a mask protects an underlying capping layer from oxidation during fabrication and cleaning processes according to embodiments of the disclosure. A buffer layer protects and stabilizes an underlying reflective multilayered stack from oxidation during fabrication processes according to embodiments of disclosure. Thus, masks according to embodiments of the disclosure include one or more of a buffer layer and a protection layer to protect one or more structures of the mask from undesired oxidation, and thereby prolong the lifetime of the mask.

According to an embodiment, a method of manufacturing a mask includes forming a reflective multilayered stack over a substrate, forming a capping layer over the reflective multilayered stack, and forming an absorber layer over the capping layer. The method further includes forming at least one of the following: a buffer layer over the reflective multilayered stack before forming the capping layer, and a protection layer over the capping layer before forming the absorber layer. The buffer layer includes one or more of a transition metal element and a compound including a transition metal element, and the protection layer includes one or more of an oxide including a transition metal element and a chloride including a transition metal element. In an embodiment, the method includes forming the buffer layer over the reflective multilayered stack before forming the capping layer. In an embodiment, the buffer layer includes the compound including the transition metal element. In an embodiment, the buffer layer includes one or more of a halide including the transition metal element, an oxide including the transition metal element, a nitride including the transition metal element, a carbide including the transition metal element, and a boride including the transition metal element. In an embodiment, the buffer layer includes one or more of tantalum oxide, ruthenium oxide, niobium oxide, rhodium oxide, tantalum nitride, ruthenium nitride, niobium nitride, rhodium nitride, tantalum carbide, ruthenium carbide, niobium carbide, rhodium carbide, tantalum boride, ruthenium boride, niobium boride, rhodium boride, tantalum fluoride, ruthenium fluoride, niobium fluoride, rhodium fluoride, tantalum chloride, ruthenium chloride, niobium chloride, rhodium chloride, tantalum bromide, ruthenium bromide, niobium bromide, rhodium bromide, tantalum iodide, ruthenium iodide, niobium iodide, and rhodium iodide. In an embodiment, the method includes forming the protection layer over the capping layer before forming the absorber layer. In an embodiment, the protection layer includes one or more ruthenium oxide, ruthenium chloride, rhodium oxide, and rhodium chloride. In an embodiment, the protection layer includes the chloride including the transition metal element. In an embodiment, the method further includes forming a circuit pattern in the absorber layer.

According to another embodiment, a method of manufacturing a mask includes forming a reflective multilayered stack over a substrate, forming a buffer layer over the reflective multilayered stack, wherein the buffer layer includes one or more of a halide, an oxide, a nitride, a carbide, or a boride of a transition metal element; forming a capping layer over the buffer layer; and forming an absorber layer over the capping layer. In an embodiment, the buffer layer includes one or more of tantalum oxide, ruthenium oxide, niobium oxide, rhodium oxide, tantalum nitride, ruthenium nitride, niobium nitride, rhodium nitride, tantalum carbide, ruthenium carbide, niobium carbide, rhodium carbide, tantalum boride, ruthenium boride, niobium boride, rhodium boride, tantalum fluoride, ruthenium fluoride, niobium fluoride, rhodium fluoride, tantalum chloride, ruthenium chloride, niobium chloride, rhodium chloride, tantalum bromide, ruthenium bromide, niobium bromide, rhodium bromide, tantalum iodide, ruthenium iodide, niobium iodide, and rhodium iodide. In an embodiment, the method further includes forming an anti-reflection layer over the absorber layer. In an embodiment, the method further includes forming a circuit pattern in the anti-reflection layer and the absorber layer to expose a portion of the capping layer. In an embodiment, the buffer layer is formed using a physical vapor deposition process.

According to another embodiment, method of manufacturing a mask includes forming a reflective multilayered stack over a substrate; forming a capping layer over the reflective multilayered stack; forming a protection layer over the capping layer, wherein the protection layer includes one or more of a halide or an oxide including a transition metal element or of an alloy of two or more transition metal elements; and forming an absorber layer over the protection layer. In an embodiment, the method further includes forming a circuit pattern in the absorber layer to expose a portion of the protection layer. In an embodiment, the protection layer includes one or more ruthenium oxide, ruthenium chloride, rhodium oxide, and rhodium chloride. In an embodiment, the protection layer is formed using a physical vapor deposition process.

According to another embodiment, a method of manufacturing a semiconductor device includes directing extreme ultraviolet (EUV) radiation to a mask, and reflecting patterned light from the mask and onto a photoresist layer disposed on a semiconductor substrate. The mask includes a reflective multilayered stack disposed over a mask substrate, a capping layer disposed over the reflective multilayered stack, an absorber layer disposed over the capping layer, and at least one of: a buffer layer disposed between the reflective multilayered stack and the capping layer, and a protection layer disposed between the capping layer and the absorber layer. The buffer layer includes one or more of a transition metal element and a compound including a transition metal element. The protection layer includes one or more of an oxide including a transition metal element and a chloride including a transition metal element. In an embodiment, the mask includes the buffer layer. In an embodiment, the buffer layer includes one or more of a halide including the transition metal element, an oxide including the transition metal element, a nitride including the transition metal element, a carbide including the transition metal element, and a boride including the transition metal element. In an embodiment, the mask includes the protection layer. In an embodiment, the protection layer includes one or more of ruthenium oxide, ruthenium chloride, rhodium oxide, and rhodium chloride. In an embodiment, the mask includes the buffer layer and the protection layer. In an embodiment, the buffer layer includes one or more of tantalum oxide, ruthenium oxide, niobium oxide, and rhodium oxide, and the protection layer includes one or more of ruthenium chloride and rhodium chloride. In an embodiment, the buffer layer has a thickness ranging from 0.5 nm to 10 nm. In an embodiment, the protection layer has a thickness ranging from 0.5 nm to 10 nm.

According to another embodiment, a method of manufacturing a semiconductor device includes directing extreme ultraviolet (EUV) radiation to a mask; and reflecting patterned light from the mask and onto a photoresist layer disposed on a semiconductor substrate. The mask includes a reflective multilayered stack disposed over a mask substrate; a buffer layer disposed over the reflective multilayered stack, the buffer layer including one or more of a halide, an oxide, a nitride, a carbide, or a boride of a transition metal element; a capping layer disposed over the buffer layer; and an absorber layer disposed over the capping layer. In an embodiment, the buffer layer includes one or more of tantalum oxide, ruthenium oxide, niobium oxide, rhodium oxide, tantalum nitride, ruthenium nitride, niobium nitride, rhodium nitride, tantalum carbide, ruthenium carbide, niobium carbide, rhodium carbide, tantalum boride, ruthenium boride, niobium boride, rhodium boride, tantalum fluoride, ruthenium fluoride, niobium fluoride, rhodium fluoride, tantalum chloride, ruthenium chloride, niobium chloride, rhodium chloride, tantalum bromide, ruthenium bromide, niobium bromide, rhodium bromide, tantalum iodide, ruthenium iodide, niobium iodide, and rhodium iodide. In an embodiment, the buffer layer has a thickness ranging from 0.5 nm to 10 nm. In an embodiment, the capping layer has a thickness ranging from 1 nm to 7 nm. In an embodiment, the mask further includes an anti-reflection layer disposed over the absorber layer.

According to another embodiment, a method of manufacturing a semiconductor device, the method includes directing extreme ultraviolet (EUV) radiation to a mask; and reflecting patterned light from the mask and onto a photoresist layer disposed on a semiconductor substrate. The mask includes a reflective multilayered stack disposed over a mask substrate; a capping layer disposed over the reflective multilayered stack; a protection layer disposed over the capping layer, wherein the protection layer includes one or more of a halide including a transition metal element or an oxide including a transition metal element; and an absorber layer disposed over the protection layer. In an embodiment, the protection layer includes the oxide including the transition metal element. In an embodiment, the protection layer includes the halide including the transition metal element. In an embodiment, the protection layer includes one or more ruthenium oxide, ruthenium chloride, rhodium oxide, and rhodium chloride. In an embodiment, the protection layer has a thickness ranging from 0.5 nm to 10 nm. In an embodiment, the capping layer has a thickness ranging from 1 nm to 7 nm.

According to another embodiment, a mask for EUV photolithography includes a reflective multilayered stack disposed over a substrate; a capping layer disposed over the reflective multilayered stack; an absorber layer disposed over the capping layer; and at least one of: a buffer layer disposed between the reflective multilayered stack and the capping layer, and a protection layer disposed between the capping layer and the absorber layer. The buffer layer includes one or more of a transition metal element or a compound including a transition metal element. The protection layer includes one or more of an oxide including a transition metal element and a chloride including a transition metal element. In an embodiment, the mask includes the buffer layer. In an embodiment, the buffer layer includes one or more of tantalum oxide, ruthenium oxide, niobium oxide, and rhodium oxide. In an embodiment, the mask includes the protection layer. In an embodiment, the protection layer includes one or more of ruthenium oxide, ruthenium chloride, rhodium oxide, and rhodium chloride. In an embodiment, the mask includes the buffer layer and the protection layer. In an embodiment, the buffer layer includes one or more of tantalum oxide, ruthenium oxide, niobium oxide, and rhodium oxide, and the protection layer includes one or more of ruthenium chloride and rhodium chloride. In an embodiment, the absorber layer is un-patterned. In an embodiment, the absorber layer includes a pattern including one or more openings.

According to another embodiment, a mask for EUV photolithography includes a reflective multilayered stack disposed over a substrate; a buffer layer disposed over the reflective multilayered stack, the buffer layer includes one or more of a halide, an oxide, a nitride, a carbide, or a boride of a transition metal element; a capping layer disposed over the buffer layer; and an absorber layer disposed over the capping layer. In an embodiment, the absorber layer is un-patterned. In an embodiment, the absorber layer includes a pattern including one or more openings exposing the capping layer. In an embodiment, the buffer layer includes one or more of tantalum oxide, ruthenium oxide, niobium oxide, rhodium oxide, tantalum nitride, ruthenium nitride, niobium nitride, rhodium nitride, tantalum carbide, ruthenium carbide, niobium carbide, rhodium carbide, tantalum boride, ruthenium boride, niobium boride, rhodium boride, tantalum fluoride, ruthenium fluoride, niobium fluoride, rhodium fluoride, tantalum chloride, ruthenium chloride, niobium chloride, rhodium chloride, tantalum bromide, ruthenium bromide, niobium bromide, rhodium bromide, tantalum iodide, ruthenium iodide, niobium iodide, and rhodium iodide. In an embodiment, the buffer layer has a thickness ranging from 0.5 nm to 10 nm. In an embodiment, the capping layer has a thickness ranging from 1 nm to 7 nm. In an embodiment, the mask further includes an anti-reflection layer disposed over the absorber layer.

According to another embodiment, a mask for EUV photolithography includes a reflective multilayered stack disposed over a substrate; a capping layer disposed over the reflective multilayered stack; a protection layer disposed over the capping layer, wherein the protection layer includes one or more of a halide including a transition metal element or an oxide including a transition metal element; and an absorber layer disposed over the protection layer. In an embodiment, the absorber layer is un-patterned. In an embodiment, the absorber layer includes a pattern including one or more openings exposing the protection layer. In an embodiment, the protection layer includes one or more ruthenium oxide, ruthenium chloride, rhodium oxide, and rhodium chloride. In an embodiment, the protection layer has a thickness ranging from 0.5 nm to 10 nm.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a mask, the method comprising:
forming a reflective multilayered stack over a substrate;
depositing a buffer layer over the reflective multilayered stack, wherein the buffer layer comprises one or more of a halide, an oxide, a nitride, a carbide, or a boride of at least one transition metal element, and the at least one transition metal element includes at least one of tantalum, ruthenium, niobium, and rhodium;
depositing a capping layer over the buffer layer; and
depositing an absorber layer over the capping layer.

2. The method of claim 1, wherein the buffer layer comprises at least one of tantalum oxide, ruthenium oxide, niobium oxide, or rhodium oxide.

3. The method of claim 1, further comprising forming an anti-reflection layer over the absorber layer.

4. The method of claim 3, further comprising forming a circuit pattern in the anti-reflection layer and the absorber layer to expose a portion of the capping layer.

5. The method of claim 1, wherein the buffer layer is formed using an ion beam deposition process.

6. The method of claim 1, wherein the buffer layer is formed using a physical vapor deposition process.

7. A method of manufacturing a mask, the method comprising:
forming a reflective multilayered stack over a substrate;
depositing a capping layer over the reflective multilayered stack;
depositing a protection layer including at least one transition metal element over the capping layer, wherein the protection layer comprises one or more of a halide of the at least one transition metal element or an oxide of the at least one transition metal element, and the at one transition metal element includes at least one of rhodium or ruthenium; and
depositing an absorber layer over the protection layer.

8. The method of claim 7, further comprising forming a circuit pattern in the absorber layer to expose a portion of the protection layer.

9. The method of claim 7, wherein the protection layer comprises the halide of the at least one transition metal element.

10. The method of claim 7, wherein the protection layer comprises the oxide of the at least one transition metal element.

11. The method of claim 7, wherein the protection layer comprises ruthenium oxide.

12. The method of claim 7, wherein the protection layer is formed using an ion beam deposition process.

13. The method of claim 7, wherein the protection layer is formed using a physical vapor deposition process.

14. A mask for extreme ultraviolet (EUV) photolithography comprising:
a reflective multilayered stack disposed over a substrate;
a buffer layer disposed over the reflective multilayered stack, the buffer layer comprising one or more of a halide, an oxide, a nitride, a carbide, or a boride of a transition metal element;
a capping layer disposed over the buffer layer; and
an absorber layer disposed over the capping layer.

15. The mask of claim 14, wherein the absorber layer is un-patterned.

16. The mask of claim 14, wherein the absorber layer includes a pattern including one or more openings exposing the capping layer.

17. The mask of claim 14, wherein the buffer layer comprises at least one of tantalum nitride, ruthenium nitride, niobium nitride, rhodium nitride, or tantalum carbide.

18. The mask of claim 14, wherein the buffer layer has a thickness ranging from 0.5 nm to 10 nm.

19. The mask of claim 14, wherein the capping layer has a thickness ranging from 1 nm to 7 nm.

20. The mask of claim 14, further comprising an anti-reflection layer disposed over the absorber layer.
